(19) United States
(12) Patent Application Publication
(10) Pub. No.: US 2026/0182122 A1
(43) Pub. Date: Jun. 25, 2026

(54) DISPLAY APPARATUS

(71) Applicant: SAMSUNG ELECTRONICS CO., LTD., Suwon-si (KR)

(72) Inventors: Seungjae KIM, Suwon-si (KR); Pilyong OH, Suwon-si (KR); Jaemin CHO, Suwon-si (KR); Kwangjae LEE, Suwon-si (KR)

(73) Assignee: SAMSUNG ELECTRONICS CO., LTD., Suwon-si (KR)

(21) Appl. No.: 19/388,497

(22) Filed: Nov. 13, 2025

Related U.S. Application Data
(63) Continuation of application No. PCT/KR2025/017786, filed on Nov. 3, 2025.

(30) Foreign Application Priority Data
Dec. 23, 2024 (KR) 10-2024-0194121

(51) Int. Cl. H10H 29/85

(52) U.S. Cl. CPC H10H 29/8506; H10H 29/8581

(57) ABSTRACT

A display apparatus includes a display module, a frame configured to support the display module, and an adhesive configured to be cured between the display module and the frame. The frame includes a panel on a rear surface of the display module and a support bar on a rear side of the panel, wherein the support bar is configured to prevent and/or reduce warping of the display module and/or the panel due to a temperature change after curing the adhesive.

### CROSS-REFERENCE TO RELATED APPLICATION(S)

This application is a continuation of International Application No. PCT/KR2025/017786, filed on Nov. 3, 2025, which claims priority to Korean Patent Application No. 10-2024-0194121, filed on Dec. 23, 2024 in the Korean Intellectual Property Office, the disclosures of which are incorporated by reference herein in their entirety.

### BACKGROUND

### 1. Field

The disclosure relates to a display apparatus having an improved structure.

### 2. Description of Related Art

A display apparatus is a type of output device that visually displays data information, such as characters and graphics, as well as images.

In general, display apparatuses have mainly used a liquid crystal panel that requires a backlight, or an organic light-emitting diode (OLED) panel made of a film of organic compounds that emits light by itself in response to an electric current. However, liquid crystal panels have disadvantages such as a slow response time, high power consumption, and the inability to emit light on their own—requiring a backlight—which makes compact design difficult. In addition, although OLED panels do not require a backlight and may be made thin because they are self-emissive, they are vulnerable to burn-in phenomena, where if the same image is displayed for a long time, the sub-pixels degrade, leaving certain parts of the previous image visible even after the display content changes.

Accordingly, as a new type of panel to replace these, micro LED or μLED display panels, in which inorganic light-emitting elements are mounted on a substrate and directly used as pixels, have been studied.

A micro LED display panel is a type of flat-panel display that includes a plurality of inorganic LEDs each having a size of 100 micrometers or less.

Although such LED panels are also self-emissive elements, they employ inorganic light-emitting elements, and thus do not suffer from the burn-in phenomenon of OLEDs, while exhibiting excellent brightness, resolution, power consumption, and durability.

Compared with liquid crystal display (LCD) panels that require a backlight, micro LED display panels offer better contrast, response time, and energy efficiency. Both organic LEDs and micro LEDs, which are inorganic light-emitting elements, are energy-efficient, but micro LEDs have higher brightness, better luminous efficiency, and longer lifespans than OLEDs.

Furthermore, by arranging LEDs on a circuit substrate in pixel units, it is possible to produce display modules on a per-substrate basis, making it easy to manufacture in various resolutions and screen sizes according to customer orders.

### SUMMARY

One or more embodiments of the present disclosure may provide a display apparatus capable of reducing and/or preventing warping, deformation, and the like caused by temperature changes.

Embodiments of the present disclosure provide a display apparatus capable of reducing and/or preventing interference between a plurality of display modules.

Embodiments of the present disclosure provide a display apparatus including a frame having an improved structure.

The scope of the present disclosure is not limited to those described above, and other technical tasks not mentioned will be clearly understood by those of ordinary skill in the art from the description below.

A display apparatus according to an embodiment of the present disclosure may include: a display module including a substrate and a plurality of inorganic light-emitting elements on the substrate; a frame configured to support the display module; and an adhesive configured to be cured between the display module and the frame. The frame may include: a panel on the rear surface of the display module with the adhesive therebetween, the panel having a first coefficient of thermal expansion (CTE); and a support bar on a rear side of the panel and having a second CTE lower than the first CTE. The support bar may be configured to prevent and/or reduce warping of the display module and/or the panel due to a temperature change after the adhesive is cured.

A display apparatus according to an embodiment of the present disclosure may include: a display module including a substrate and a plurality of inorganic light-emitting elements on the substrate; and a frame configured to support the display module. The frame may include: a panel on the rear surface of the display module and including aluminum; and a support bar on a rear side of the panel. The support bar may include steel and be configured to suppress deformation of the display module and/or the panel due to a temperature change.

### BRIEF DESCRIPTION OF DRAWINGS

FIG. 1 is a perspective view of a display apparatus according to an embodiment of the present disclosure.

FIG. 2 is an exploded view of the main components of the display apparatus according to an embodiment of the present disclosure.

FIG. 3 is an enlarged cross-sectional view of part of a display module according to an embodiment of the present disclosure.

FIG. 4 is a perspective view of the rear surface of a display module according to an embodiment of the present disclosure.

FIG. 5 is a perspective view of an assembly of a display module and a frame according to an embodiment of the present disclosure.

FIG. 6 is an exploded perspective view of the assembly of a display module and a frame according to an embodiment of the present disclosure.

FIG. 7 is a perspective view of a frame according to an embodiment of the present disclosure.

FIG. 8 is a rear perspective view of the frame according to an embodiment of the present disclosure.

FIG. 9 is a plan cross-sectional view taken along line I-I′ of FIG. 5.

FIG. 10 is an enlarged view of part A shown in FIG. 9.

FIG. 11 is an enlarged view of part B shown in FIG. 9.

FIG. 12 is a plan cross-sectional view of an assembly of a display module and a frame according to an embodiment of the present disclosure.

FIG. 13 is a plan cross-sectional view of an assembly of a display module and a frame according to an embodiment of the present disclosure.

FIG. 14 is a plan cross-sectional view of an assembly of a display module and a frame according to an embodiment of the present disclosure.

FIG. 15 is a plan cross-sectional view of part of a display apparatus according to an embodiment of the present disclosure.

FIG. 16 is a table showing warping (deformation) caused by temperature changes in each case.

### DETAILED DESCRIPTION

The various embodiments of the present disclosure and the terms used herein are not intended to limit the technical features described in this document to specific embodiments, but should be understood to include various modifications, equivalents, or alternatives of the embodiments.

In the description of the drawings, similar or related components may be denoted by similar reference numerals.

The singular form of nouns corresponding to items may include one or more of the items unless the context clearly dictates otherwise.

In this document, phrases such as “A or B,” “at least one of A and B,” “at least one of A or B,” “A, B, or C,” “at least one of A, B, and C,” and “at least one of A, B, or C” may each include any one of the listed items or any possible combination thereof.

The term “and/or” includes combinations of a plurality of related described components or any one of the plurality of related described components.

The terms “unit,” “module,” and “member” may be implemented in hardware or software. Depending on the embodiments, a plurality of “units,” “modules,” or “members” may be implemented as a single component, or one “unit,” “module,” or “member” may include a plurality of components.

The terms “first,” “second,” “third,” “primary,” “secondary,” “tertiary,” etc., may be used simply to distinguish one component from another component, and do not limit the components in other aspects such as importance or sequence.

When a (first) component is referred to as being “coupled” or “connected” to another (second) component, with or without the terms “functionally” or “communicatively,” this means that the component can be connected directly (e.g., wired), wirelessly, or via a third component.

The terms “include” or “have” and variations thereof are intended to specify the presence of the stated features, integers, steps, operations, components, parts, or combinations thereof, but do not preclude the presence or addition of one or more other features, integers, steps, operations, components, parts, or combinations thereof.

When a component is described as being “connected,” “coupled,” “supported,” or “in contact” with another component, it includes both cases where the components are directly connected, coupled, supported, or in contact, and cases where they are indirectly connected, coupled, supported, or in contact through a third component.

When a component is described as being “on” another component, it includes both cases where the component is in contact with the other component, and cases where another component is present between the two components.

The meaning of “identical” includes having similar properties or being similar within a certain range, and also includes “substantially identical.” “Substantially identical” means that a difference within a range that is meaningless in relation to a numerical value or reference value, and within manufacturing tolerances, is considered within the scope of “identical.”

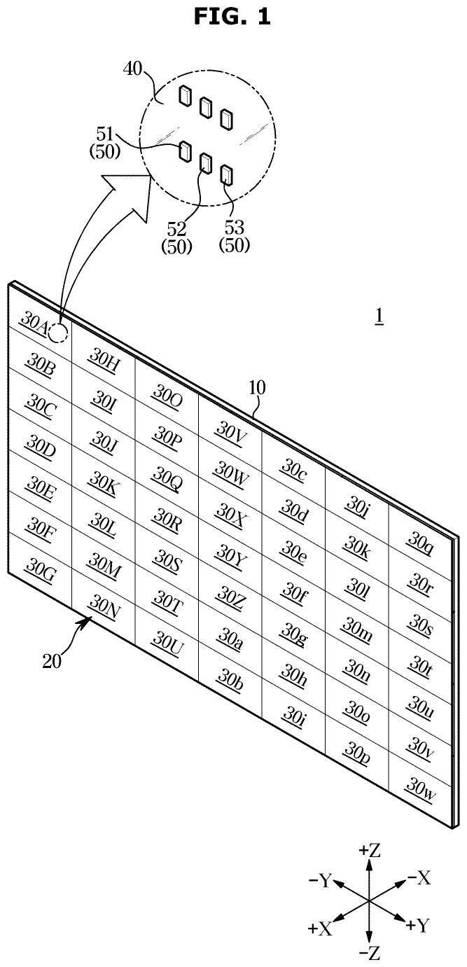

Meanwhile, the terms “front,” “rear,” “left,” “right,” “upper,” and “lower” used in the following description are defined based on the drawings and do not limit the shape and position of each component. For example, “front” and “rear” may be defined based on the X-axis shown in the drawings; “left” and “right” based on the Y-axis; “upper” and “lower” based on the Z-axis. For example, in a display apparatus 1 shown in FIG. 1, the direction in which images are displayed may be defined as the front (+X direction), and the opposite direction as the rear (−X direction). For example, the front (+X direction) may be substantially the same as the emission direction of the plurality of inorganic light-emitting elements 50.

In the drawings, some components of a display apparatus 1, including a plurality of inorganic light-emitting elements 50, may be micro-sized components having dimensions of several μm to several hundred μm, and for convenience of explanation, the scales of some components (e.g., the plurality of inorganic light-emitting elements 50, a substrate 40, a frame 100, etc.) may be exaggerated.

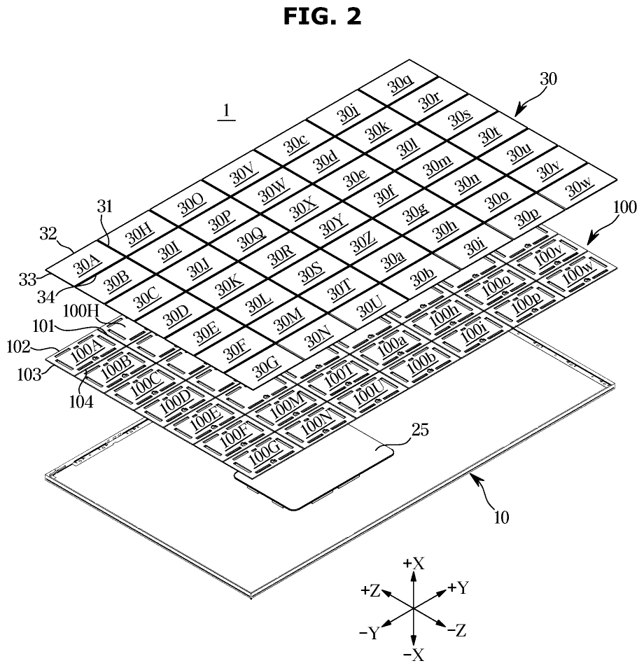

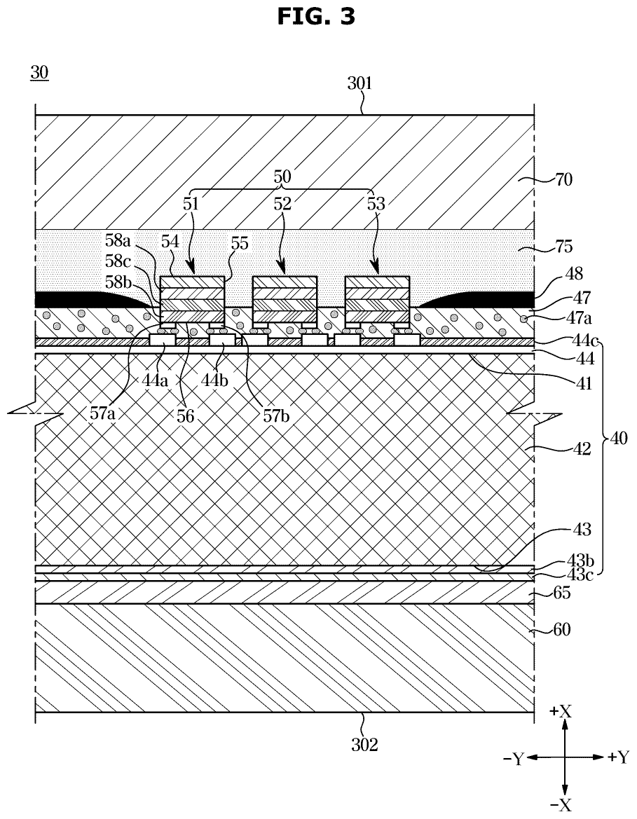

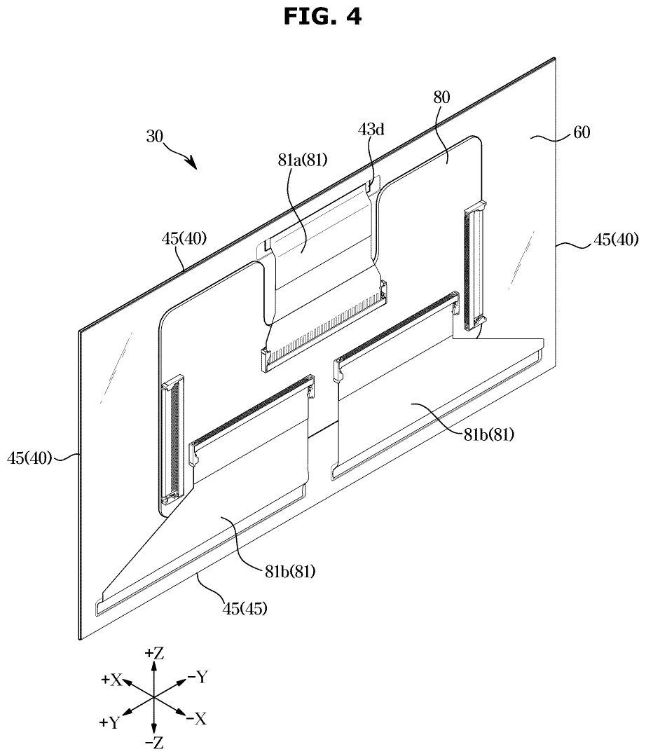

FIG. 1 is a perspective view of a display apparatus according to an embodiment of the present disclosure. FIG. 2 is an exploded view of the main components of the display apparatus according to an embodiment of the present disclosure. FIG. 3 is an enlarged cross-sectional view of part of a display module according to an embodiment of the present disclosure. FIG. 4 is a perspective view of the rear surface of a display module according to an embodiment of the present disclosure.

The display apparatus 1 may be an appliance that displays information, data, and the like in the form of characters, graphics, charts, and images. For example, the display apparatus 1 may be implemented as televisions (TVs), personal computers (PCs), mobile devices, digital signage, or the like.

The display apparatus 1 may include a display panel 20. The display panel 20 may be configured to display an image.

The display panel 20 may include a plurality of display modules 30A-30w. The display panel 20 may include a driving board for driving each of the display modules 30A-30w and a Timing Controller (TCON) board for generating timing signals necessary for controlling each of the display modules 30A-30w.

Hereinafter, a display module may be referred to as a display module 30, and the description of display module 30 may apply to each of the plurality of display modules 30A-30w.

The display apparatus 1 may include a board 25. The board 25 may be configured to drive and/or control the display panel 20. The board 25 may include a circuit board for driving and/or controlling the display apparatus 1. For example, the board 25 may include at least one of a power board for supplying power to the display panel 20; a control board for controlling the overall operation of the display panel 20; and a communication board for communication with external devices.

The display apparatus 1 may include a frame 100. The display apparatus 1 may include a plurality of frames 100A-100w configured to support the plurality of display modules 30A-30w. Each of the plurality of frames 100A-100w may correspond to each of the plurality of display modules 30A-30w. Each of the plurality of frames 100A-100w may support each of the plurality of display modules 30A-30w.

Hereinafter, a frame may be referred to as a frame 100, and the description of the frame 100 may apply to each of the plurality of frames 100A-100w.

The display apparatus 1 may include a chassis 10. The chassis 10 may be configured to cover the rear of the display panel 20. The chassis 10 may be provided to cover the rear of the plurality of display modules (30A-30w) and/or the rear of the plurality of frames 100A-100w. The chassis 10 may form the rear appearance of the display apparatus 1.

The chassis 10 may be installed on the floor via a stand or mounted on a wall via a hanger. The chassis 10 may also be referred to as a case 10, housing 10, or rear cover 10.

Referring to FIGS. 1 and 2, the plurality of display modules 30A-30w may be arranged adjacent to each other in both vertical and horizontal directions. The plurality of display modules 30A-30w may be arranged in an M×N matrix form. In the present embodiment, the plurality of display modules 30A-30w, totaling forty-nine, are provided in a 7×7 matrix arrangement; however, the number and arrangement of the plurality of display modules 30A-30w are not limited thereto.

Each of the plurality of display modules 30A-30w may be mounted to the plurality of frames 100A-100w. Each of the plurality of display modules 30A-30w may be coupled to the plurality of frames 100A-100w. The plurality of display modules 30A-30w and the plurality of frames 100A-100w may correspond one-to-one. For example, the display module 30A may correspond to a first frame 100A.

As illustrated, the display modules 30A-30w arranged in a matrix type may be applied to display apparatuses, such as PC monitors, high-resolution TVs, digital signage, and electronic displays.

Alternatively, each of the display modules 30A-30w may be applied as a single unit to one or more wearable devices, portable devices, handheld devices, and various other electronic products or automotive applications requiring a display. In other words, the display apparatus 1 may include a single display module 30.

The plurality of display modules 30A-30w may have the same configuration. Therefore, the description of any one display module 30 may also apply to any one or more of the plurality of display modules 30A-30w.

The display module 30 may have a quadrangular shape. The display module 30 may have a rectangle or square, or other polygonal or geometric shape, and is not particularly limited. The display module 30 may include four edges 31, 32, 33, and 34, with one pair 31 and 33 forming shorter sides and the other pair 32 and 34 forming longer sides.

The plurality of frames 100A-100w may have the same configuration. Therefore, the description of any one frame 100 may also apply to any one or more of the plurality of frames 100A-100w.

The frame 100 may have a quadrangular shape. The frame 100 may have a rectangle or square, or other polygonal or geometric shape, and is not particularly limited. The frame 100 may include four edges 101, 102, 103, and 104, with one pair 101 and 103 forming shorter sides and the other pair 102 and 104 forming longer sides.

Referring to FIG. 3, the display module 30 may include the substrate 40 and a plurality of inorganic light-emitting elements 50 mounted on the substrate 40. The plurality of inorganic light-emitting elements 50 may be mounted on a mounting surface 41 of the substrate 40. In FIG. 3, the thicknesses of some components, such as the substrate 40, may be exaggerated for convenience of explanation.

The substrate 40 may be quadrangular in shape and may correspond in shape to the display module 30. The substrate 40 may be provided as a rectangle or square shape, however, the shape is not particularly limited thereto and any suitable shape may be implemented.

The substrate 40 may include a base substrate 42, the mounting surface 41 formed on one side of the base substrate 42, a rear surface 43 formed on the opposite side of the base substrate 42 facing away from the mounting surface 41, and side surfaces 45 (see FIG. 4) disposed between the mounting surface 41 and the rear surface 43.

The mounting surface 41 may be arranged to face the plurality of inorganic light-emitting elements 50 and may face a cover 70, which will be described later. The rear surface 43 may be arranged to face the chassis 10.

The substrate 40 may include a Thin Film Transistor (TFT) layer 44 configured to drive the inorganic light-emitting elements 50. The TFT layer 44 may be formed on the base substrate 42. The substrate 40 (particularly, the base substrate 42) may include glass material, and in this case, the substrate 40 may be referred to as a glass substrate 40. That is, the substrate 40 may include a Chip-on-Glass (COG) type of substrate. Furthermore, any suitable glass material may be used, including but not limited to one or more of silicon oxides (i.e., silica, silicon dioxide, SiO₂, SiOₓ), silicon oxynitrides (SiOₓN_{y}), borosilicate glass (BSG), phosphosilicate glass (PSG), borophosphosilicate glass (BPSG), etc.

The TFTs of the TFT layer 44 are not limited to a specific structure or type, and may be implemented in various embodiments, such as Low-Temperature Polycrystalline Silicon (LTPS) TFTs, oxide TFTs, Si (poly-Si or a-Si) TFTs, as well as organic TFTs, graphene TFTs, or the like.

When the base substrate 42 of the substrate 40 is a silicon wafer, the TFT layer 44 may be replaced with a Complementary Metal-Oxide-Semiconductor (CMOS) type or with n-type MOS field-effect transistors (MOSFETs) or p-type MOSFETs.

The substrate 40 may include a first pad electrode 44a and a second pad electrode 44b configured to electrically connect the plurality of inorganic light-emitting elements 50 to the TFT layer 44. For example, the first and second pad electrodes 44a and 44b may be provided as a pair.

The plurality of inorganic light-emitting elements 50 may be formed of an inorganic material, and may have dimensions in the range of several μm to several tens of μm in width, length, and/or height. For example, the inorganic light-emitting element 50 may have its shortest dimension at 100 μm or less. For example, the inorganic light-emitting element 50 may be picked up from a sapphire or silicon wafer and transferred to the substrate 40. The wafer material may comprise any suitable material including but not limited to silicon-on-insulator (SOI), germanium (Ge), and/or silicon-germanium (SiGe). For example, the inorganic light-emitting element 50 may be picked up and transferred by various methods, such as an electrostatic method using an electrostatic head or a stamping method using an elastic polymer material such as PDMS or silicone as a head. However, the present disclosure is not limited to the above examples, and the inorganic light-emitting element 50 may be mounted on the substrate 40 by various methods.

The plurality of inorganic light-emitting elements 50 may also be referred to as a plurality of micro LEDs 50, and the plurality of display modules 30A-30w may be referred to as a plurality of micro LED modules 30A-30w.

For example, each inorganic light-emitting element 50 may be a light-emitting structure including a first semiconductor 58a, an active layer 58c, a second semiconductor 58b, a first contact electrode 57a, and a second contact electrode 57b.

Each of the plurality of inorganic light-emitting elements 50 may include the first semiconductor 58a and the second semiconductor 58b. The second semiconductor 58b may be positioned closer to the substrate 40 than the first semiconductor 58a. The first semiconductor 58a and the second semiconductor 58b may be arranged with the active layer 58c interposed therebetween. One of the first semiconductor 58a and the second semiconductor 58b may be an n-type semiconductor, and the other may be a p-type semiconductor. Electrons may be present in one of the first semiconductor 58a and the second semiconductor 58b, and holes may be present in the other of the first semiconductor 58a and the second semiconductor 58b. Light may be generated during recombination of electrons and holes in the active layer 58c.

Each of the plurality of inorganic light-emitting elements 50 may include the active layer 58c. The active layer 58c may contain a material that emits light through recombination of electrons and holes. The active layer 58c may be disposed between the first semiconductor 58a and the second semiconductor 58b. The active layer 58c may be formed therebetween. The active layer 58c may be configured to emit light.

Each of the plurality of inorganic light-emitting elements 50 may include a light-emitting surface 54. The inorganic light-emitting element 50 may include a bottom surface 56 positioned opposite the light-emitting surface 54, and a side surface 55 connecting the light-emitting surface 54 and the bottom surface 56. The light-emitting surface 54 may be oriented toward the front. The light-emitting surface 54 may emit light toward the cover 70.

Each of the plurality of inorganic light-emitting elements 50 may include the first contact electrode 57a and the second contact electrode 57b. One of the first contact electrode 57a and the second contact electrode 57b may be electrically connected to the first semiconductor 58a, and the other may be electrically connected to the second semiconductor 58b. The first contact electrode 57a may be configured to correspond to the first pad electrode 44a, and the second contact electrode 57b may be configured to correspond to the second pad electrode 44b. For example, the first contact electrode 57a and the second contact electrode 57b may be provided as a pair.

For example, the first contact electrode 57a and the second contact electrode 57b may be horizontally arranged and oriented in the same direction (opposite to the light-emitting direction) in a flip-chip configuration.

The first contact electrode 57a and the second contact electrode 57b may be formed on the bottom surface 56. In other words, the first contact electrode 57a and the second contact electrode 57b may be arranged on the opposite side of the light-emitting surface 54, and thus positioned opposite to a direction in which light is emitted. The first contact electrode 57a and the second contact electrode 57b may be arranged to face the mounting surface 41 and electrically connect to the TFT layer 44. The light emitting surface 54 may be arranged to emit light in a direction opposite to the direction in which the first contact electrode 57a and the second contact electrode 57b are arranged.

Accordingly, light generated in the active layer 58c may be emitted through the light-emitting surface 54 without interference with the first contact electrode 57a and/or the second contact electrode 57b.

The first contact electrode 57a and the second contact electrode 57b may be electrically connected to the first pad electrode 44a and the second pad electrode 44b, respectively, formed on the mounting surface 41 of the substrate 40.

The display module 30 may include a conductive adhesive layer 47 configured to electrically connect the inorganic light-emitting element 50 to the substrate 40. The conductive adhesive layer 47 may mediate the electrical bonding between the contact electrodes 57a and 57b and the pad electrodes 44a and 44b, respectively. The conductive adhesive layer 47 may electrically bond the first contact electrode 57a to the first pad electrode 44a and the second contact electrode 57b to the second pad electrode 44b. The conductive adhesive layer 47 may be disposed on the substrate 40, with at least a portion positioned between the first contact electrode 57a and the first pad electrode 44a, and between the second contact electrode 57b and the second pad electrode 44b.

For example, the conductive adhesive layer 47 may be an anisotropic conductive layer. The anisotropic conductive layer may be an anisotropic conductive adhesive attached to a protective film, having a structure in which conductive balls 47a are dispersed in an adhesive resin. The conductive balls 47a, being conductive particles (e.g., spheres or other shapes) enclosed by a thin insulating film, may electrically connect conductors when the thin insulating film is broken under pressure.

When the plurality of inorganic light-emitting elements 50 are mounted on the substrate 40, pressure applied to the anisotropic conductive layer may break the insulating film of the conductive balls 47a, electrically connecting the contact electrodes 57a and 57b of the inorganic light-emitting elements 50 to the pad electrodes 44a and 44b of the substrate 40.

The anisotropic conductive layer 47 may include an anisotropic conductive film (ACF) in film form and/or an anisotropic conductive paste (ACP) in paste form.

However, the present disclosure is not limited to the above examples, and the conductive adhesive layer 47 may include solder or any other suitable conductive material(s). After the plurality of inorganic light-emitting elements 50 are aligned on the substrate 40, they may be bonded to the substrate 40 through a reflow process.

The plurality of inorganic light-emitting elements 50 may include red (R) light-emitting elements 51, green (G) light-emitting elements 52, and blue (B) light-emitting elements 53, arranged in sets on the mounting surface 41 of the substrate 40. Each set of red, green, and blue light-emitting elements 51, 52, and 53 may form a pixel, with each of the red, green, and blue light-emitting elements forming a sub-pixel.

For example, the red, green, and blue light-emitting elements 51, 52, and 53 may be arranged in a straight line at predetermined intervals or in other configurations, such as a triangular arrangement, although arrangements of any other suitable shape may be used as an alternative thereto or in combination therewith.

The substrate 40 may include a light-absorbing layer 44c configured to absorb ambient light to improve contrast. The light-absorbing layer 44c may be formed on the entire mounting surface 41 side of the substrate 40. The light-absorbing layer 44c may be formed between the TFT layer 44 and the conductive adhesive layer 47.

The display module 30 may further include a black matrix 48 formed between the plurality of inorganic light-emitting elements 50.

The black matrix 48 may function as a complement to the light-absorbing layer 44c formed on the entire mounting surface 41. In other words, the black matrix 48 may absorb ambient light to cause the substrate 40 to appear black, thereby improving contrast of the screen. Preferably, the black matrix 48 may be black in color.

According to an embodiment of the present disclosure, the black matrix 48 may be formed to be disposed between sets of pixels formed by the red, green, and blue light-emitting elements 51, 52, and 53. However, the black matrix 48 may also be finely formed to divide each of the light-emitting elements 51, 52, and 53, which are sub-pixels.

The black matrix 48 may be formed in a grid pattern with horizontal and vertical patterns between the pixels and/or sub-pixels.

The black matrix 48 may be formed by applying and curing light-absorbing ink onto the conductive adhesive layer 47 through an inkjet process, or by coating the conductive adhesive layer 47 with a light-absorbing film.

In other words, in the conductive adhesive layer 47 formed on the entire mounting surface 41, the black matrix 48 may be formed between the plurality of inorganic light-emitting elements 50 that are not mounted on the plurality of inorganic light-emitting elements 50.

The display module 30 may include the cover 70 configured to cover the substrate 40 and the plurality of inorganic light-emitting elements 50. The cover 70 may include a functional film with optical performance, and may protect the substrate 40 and the plurality of inorganic light-emitting elements 50 from an external force. The cover 70 may prevent foreign substances from entering the substrate 40 and the plurality of inorganic light-emitting elements 50. For example, the cover 70 may form a front surface 301 of the display module 30.

The display module 30 may include a cover adhesive layer 75 configured to attach the cover 70 to the substrate 40 and the plurality of inorganic light-emitting elements 50. The cover adhesive layer 75 may minimize light loss or reflection. For example, the cover adhesive layer 75 may be in the form of an optically clear adhesive (OCA) film such as double-sided tape, or an optically clear resin (OCR) in liquid form.

The display module 30 may include a heat dissipation member 60 configured to dissipate heat generated from the substrate 40. The heat dissipation member 60 may be attached to the rear surface 43 of the substrate 40. For example, the heat dissipation member 60 may form part of a rear surface 302 of the display module.

The display module 30 may include an adhesive tape 70 disposed between the rear surface 43 of the substrate 40 and the heat dissipation member 60 to bond them together.

The plurality of inorganic light-emitting elements 50 may be sequentially and electrically connected to a top wiring layer, side wiring, and a rear wiring layer 43b. The top wiring layer may be formed on the rear side of the conductive adhesive layer 47, the side wiring may be formed on the side surface 45 of the substrate 40, and the rear wiring layer 43b may be formed on the rear surface 43. An insulating layer 43c may be provided on the rear side of the rear wiring layer 43b to cover the rear wiring layer 43b.

Referring to FIG. 4, the display module 30 may include a driving circuit board 80 configured to electrically control the plurality of inorganic light-emitting elements 50 mounted on the mounting surface 41 of the substrate 40. The driving circuit board 80 may be formed as a printed circuit board.

The display module 30 may include a flexible film 81 connecting the driving circuit board 80 and the rear wiring layer 43b such that the driving circuit board 80 is electrically connected to the plurality of inorganic light-emitting elements 50.

One end of the flexible film 81 may be disposed on the rear surface 43 of the substrate 40 and connected to a rear connection pad 43d that is electrically connected to the plurality of inorganic light-emitting elements 50.

The rear connection pad 43d may be electrically connected to the rear wiring layer 43b, thereby electrically connecting the rear wiring layer 43b and the flexible film 81.

When electrically connected to the rear connection pad 43d, the flexible film 81 may deliver (i.e., transfer, transmit, supply, conduct) power and electrical signals from the driving circuit board 80 to the plurality of inorganic light-emitting elements 50.

For example, the flexible film 81 may be formed as a Flexible Flat Cable (FFC) or Chip-on-Film (COF).

The flexible film 81 may include a first flexible film 81a and a second flexible film 81b. The first flexible film 81a may deliver data signals from the driving circuit board 80 to the substrate 40. For example, the first flexible film 81a may be provided as a COF. The second flexible film 81b may deliver power from the driving circuit board 80 to the substrate 40. For example, the second flexible film 81b may be provided as an FFC.

Although the first flexible film 81a is illustrated in the drawings as a single piece, the present disclosure is not limited thereto, and the first flexible film 81a may be provided as a plurality of first flexible films 81a. Although the second flexible films 81b are illustrated in the drawings as a plurality, the present disclosure is not limited thereto, and a single second flexible film 81b may be provided.

The driving circuit board 80 may be electrically connected to the board 25 (see FIG. 2). The board 25 may be disposed at the rear of the frame 100 and connected to the driving circuit board 80 via a cable.

The heat dissipation member 60 may be configured to be in contact with the substrate 40. The heat dissipation member 60 and the substrate 40 may be bonded together by an adhesive tape 65 (see FIG. 3) disposed between the rear surface 43 of the substrate 40 and the heat dissipation member 60.

The heat dissipation member 60 may be formed of a material with high thermal conductivity or may be implemented in a configuration with high thermal conductivity. For example, the heat dissipation member 60 may be made of aluminum.

Heat generated from the plurality of inorganic light-emitting elements 50 mounted on the substrate 40 and the TFT layer 44 of the substrate 40 may be transferred to the heat dissipation member 60. The heat generated from the substrate 40 may be easily transferred to the heat dissipation member 60, and the substrate 40 may be prevented from rising above a certain temperature.

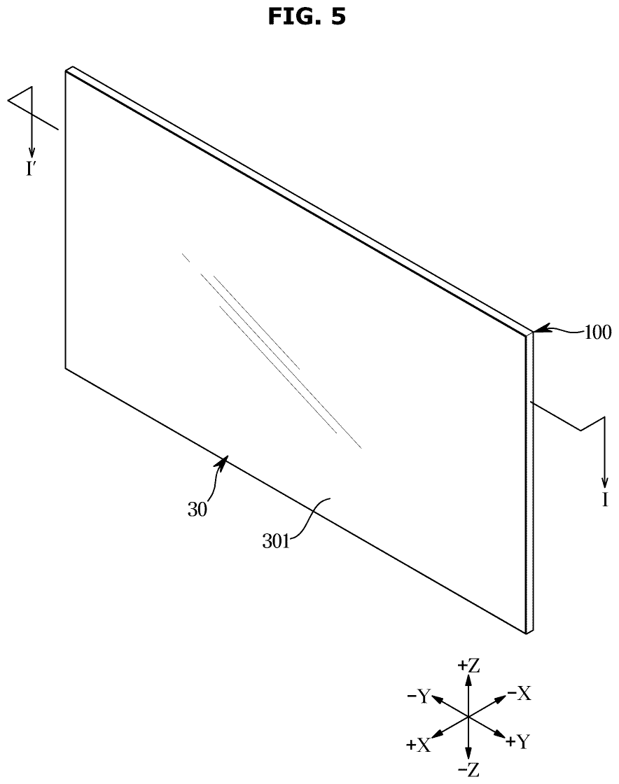

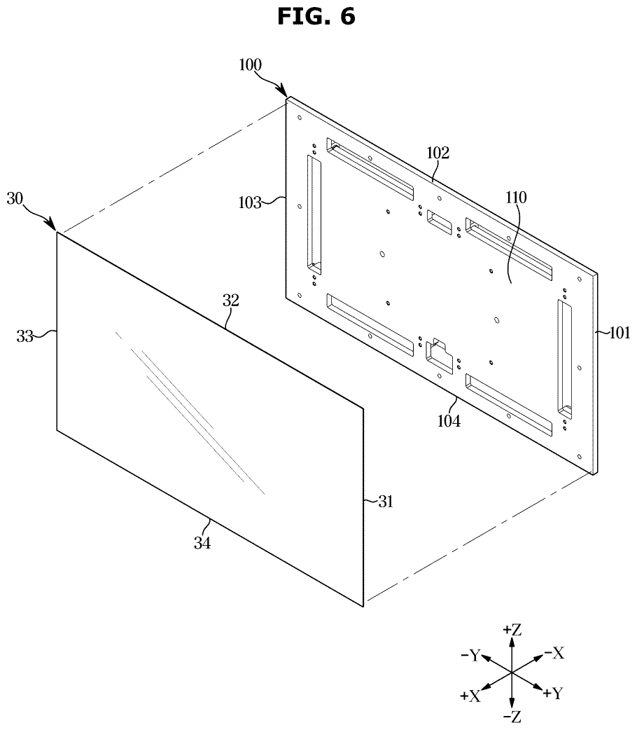

FIG. 5 is a perspective view of an assembly of a display module and a frame according to an embodiment of the present disclosure. FIG. 6 is an exploded perspective view of an assembly of a display module and a frame according to an embodiment of the present disclosure.

Referring to FIGS. 5 and 6, the frame 100 may be configured to support the display module 30. The display module 30 and the frame 100 may be coupled. With the display module 30 and the frame 100 coupled, a center of the display module 30 and a center of the frame 100 may coincide.

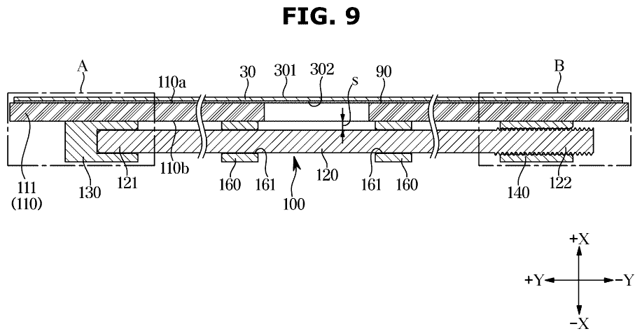

The frame 100 may be coupled to the rear of the display module 30. The frame 100 may be attached to the rear surface 302 (see FIG. 3) of the display module 30. The rear surface 302 of the display module 30 may be attached to the frame 100. An adhesive 90 (see FIG. 9) may couple the display module 30 and the frame 100.

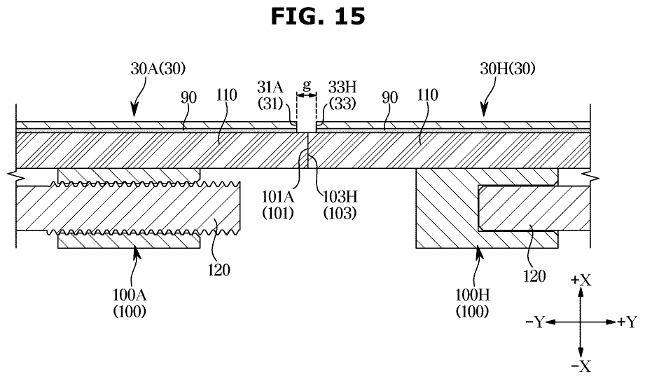

The size of the display module 30 may be smaller than that of the frame 100. The area of the display module 30 may be smaller than that of the frame 100. For example, while the display module 30 and the frame 100 are coupled, the edges 31, 32, 33, and 34 of the display module 30 may protrude outwardly, respectively, beyond or from the edges 101, 102, 103, 104 of the frame 100. The edge 31 of the display module 30 may protrude outwardly from the edge 101 of the frame 100. The edge 32 of the display module 30 may protrude outwardly from the edge 102 of the frame 100. The edge 33 of the display module 30 may protrude outwardly from the edge 103 of the frame 100. The edge 34 of the display module 30 may protrude outwardly from the edge 104 of the frame 100. Thereby, gaps g (see FIG. 15) may be formed between the plurality of display modules 30A-30w, and interference between the plurality of display modules 30A-30w may be reduced and/or prevented. This will be described in more detail later.

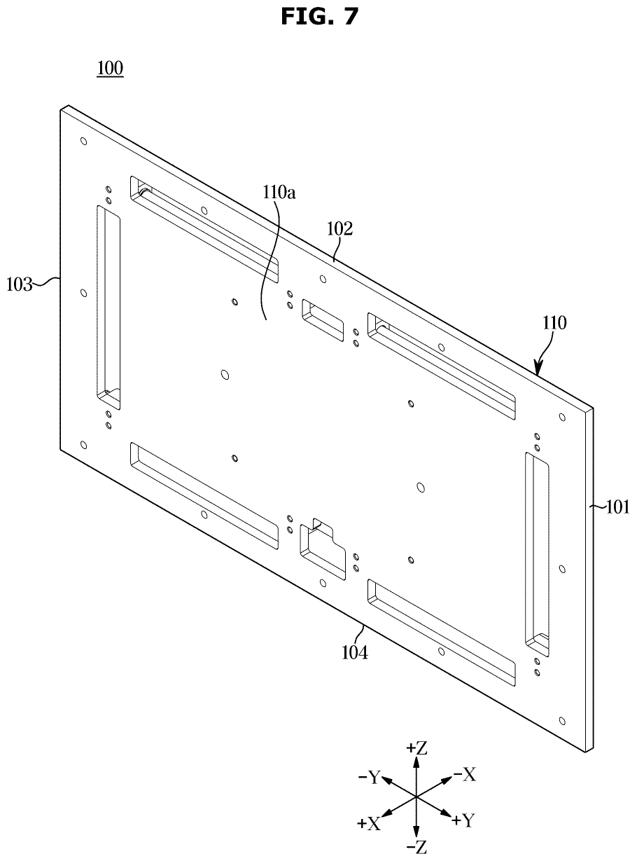

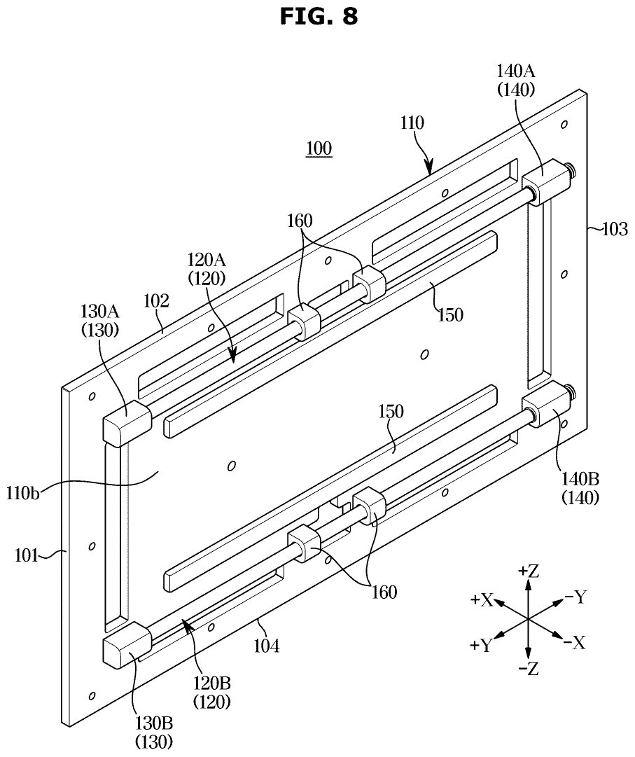

FIG. 7 is a perspective view of the frame according to an embodiment of the present disclosure. FIG. 8 is a rear perspective view of the frame according to an embodiment of the present disclosure. FIG. 9 is a plan cross-sectional view taken along line I-I′ of FIG. 5.

Referring to FIGS. 7 to 9, the frame 100 may include a panel 110 and a support bar 120.

The panel 110 may be attached to the display module 30. The panel 110 may be attached to the rear surface 302 of the display module 30. The panel 110 may be attached to the rear surface 302 of the display module 30 by adhesive 90. The front surface 110a of the panel 110 may be arranged to face the rear surface 302 of the display module 30. The rear surface 110b of the panel 110 may be arranged to face the chassis 10 (see FIG. 2).

The panel 110 may have a certain thickness in a front-rear (X) direction. For example, the front-rear (X) direction of the panel 110 may be greater than the thickness of the display module 30 in the same direction.

For example, the panel 110 may be approximately rectangular in plate shape. The edges of panel 110 may be the edges 101, 102, 103, and 104 of the frame 100.

The panel 110 may have a first coefficient of thermal expansion (CTE). The panel 110 may include aluminum, or any other suitable material having a relatively high CTE.

The support bar 120 may be provided at the rear of the panel 110. The support bar 120 may be arranged closer to the chassis 10 than the panel 110, and may be spaced rearward from the panel 110 (see a separation distance S in FIG. 9).

The support bar 120 may have a second coefficient of thermal expansion. The second coefficient of thermal expansion may be lower than the first coefficient of thermal expansion. In other words, the coefficient of thermal expansion of the support bar 120 may be lower than the coefficient of thermal expansion of the panel 110. For example, the support bar 120 may include steel, or any other suitable material having a relatively low CTE. The support bar 120 may be configured to prevent and/or reduce warping or deformation of the display module 30 and/or the panel 110. This will be described in more detail later.

The support bar 120 may include a first end portion 121 and a second end portion 122 (see FIGS. 9-11). The first end portion 121 of the support bar 120 may refer to a certain portion including one end 121a of the support bar 120, and the second end portion 122 may refer to a certain portion including the other end 122a.

Although the support bar 120 is illustrated in the drawings as extending along a long side direction (Y direction) of the panel 110, the present disclosure is not limited thereto. For example, the support bar 120 may extend along a short side direction (e.g., Z direction) of the panel 110. Also, in a case where the frame 100 has a square shape, the support bar 120 may extend along one direction without distinction between the long side direction of the panel 110 and the short side direction of the panel 110.

The frame 100 may include a plurality of support bars 120. For example, referring to FIG. 8, the frame 100 may include a first support bar 120A and a second support bar 120B. The first and second support bars 120A and 120B may have substantially the same configuration. The first and second support bars 120A and 120B may extend along the long side direction of the panel 110. The first and second support bars 120A and 120B may be spaced apart in the short side direction.

However, the present disclosure is not limited to the above examples. There are no limitations on the number, shape, position, or the like of the support bars 120. For example, the frame 100 may include a single support bar 120 disposed through the center of the frame 100. For example, the frame 100 may include a plurality of support bars 120, each extending along the short side direction of the panel 110 and spaced apart along the long side direction of the panel 110. The support bars 120 may include various shapes to inhibit deformation (warping) of the display module 30 and the panel 110.

The support bar 120 may also be referred to as a support pin 120 or a support member 120.

The frame 100 may include a first coupling portion 130. The first coupling portion 130 may be formed on the rear side of the panel 110. The first coupling portion 130 may be formed on the rear surface 110b of the panel 110. The first coupling portion 130 may protrude from the rear surface 110b of the panel 110.

The first coupling portion 130 may be configured to hold the first end portion 121 of the support bar 120. The first end portion 121 of the support bar 120 may be configured to be couplable to (i.e., attached, affixed, or otherwise secured to) the first coupling portion 130. The first end portion 121 of the support bar 120 may be configured to be secured to the first coupling portion 130. Furthermore, as used herein “couplable to” may encompass any and all suitable permanent, temporary, and/or removable coupling configurations and or methods.

The number of first coupling portions 130 may correspond to the number of support bars 120. For example, the frame 100 may include a plurality of first coupling portions 130A and 130B. The first coupling portion 130A may be coupled to the first end portion 121 of the first support bar 120A, and the first coupling portion 130B may be coupled to the first end portion 121 of the second support bar 120B.

The frame 100 may include a second coupling portion 140. The second coupling portion 140 may be formed on the rear side of the panel 110. The second coupling portion 140 may be formed on the rear surface 110b of the panel 110. The second coupling portion 140 may protrude from the rear surface 110b of the panel 110.

The second coupling portion 140 may be configured to hold the second end portion 122 of the support bar 120. The second end portion 122 of the support bar 120 may be configured to be couplable to the second coupling portion 140. The second end portion 122 of the support bar 120 may be configured to be secured to the second coupling portion 140. The second coupling portion 140 may be spaced from the first coupling portion 130. The second coupling portion 140 may be spaced from the first coupling portion 130 along an extension direction of the support bar 120.

The number of second coupling portions 140 may correspond to the number of support bars 120. For example, the frame 100 may include a plurality of second coupling portions 140A and 140B. The second coupling portion 140A may be coupled to the second end portion 122 of the first support bar 120A, and the second coupling portion 140B may be coupled to the second end portion 122 of the second support bar 120B.

The frame 100 may include a reinforcement portion 150. The reinforcement portion 150 may be configured to increase the strength of the panel 110. The reinforcement portion 150 may be formed on the rear side of the panel 110. The reinforcement portion 150 may be formed on the rear surface 110b of the panel 110. The second coupling portion 140 may protrude from the rear surface 110b of the panel 110. Although two reinforcement portions 150 are illustrated in the drawings, the number of the reinforcement portions 150 is not limited thereto.

The frame 100 may include a support portion 160. The support portion 160 may be configured to support between the first end portion 121 and the second end portion 122 of the support bar 120. The support portion 160 may reduce and/or prevent deflection of the support bar 120. The support portion 160 may include a through-hole 161 into which the support bar 120 is inserted. Although two support portions 160 are illustrated in the drawings as supporting one support bar 120, the number of the support portions 160 is not limited thereto.

Referring to FIG. 9, the adhesive 90 may be provided to couple the display module 30 and the frame 100. The adhesive 90 may be provided to join the display module 30 and the frame 100. The adhesive 90 may be disposed between the display module 30 and the frame 100. The adhesive 90 may be disposed between the rear surface 302 of the display module 30 and the front surface 110a of the panel 110.

The adhesive 90 may be configured to be cured between the display module 30 and the frame 100. The adhesive 90 may be configured to set and/or be cured in a high-temperature environment. Here, the high temperature may be a temperature that is relatively higher than room temperature. For example, the adhesive 90 may include an epoxy resin. For example, the adhesive 90 may be cured in a range of approximately 75° C. to 100° C. As the adhesive 90 cures, the display module 30 and the frame 100 may be bonded. As the adhesive 90 cures, the display module 30 and the frame 100 may be coupled. The display module 30 and the frame 100 may be coupled to each other by the adhesive 90 to form an assembly.

Generally, when components of different materials are bonded to each other with an adhesive, the assembly of the components of different materials may deform due to one or more temperature changes. A display module and a frame bonded with an adhesive may have different physical properties and may warp due to one or more temperature changes. For example, when the adhesive between the display module and the frame is cured at a high temperature and then exposed to a room-temperature environment, the display module and the frame may warp due to differences in their physical properties. Depending on the difference between the thermal contraction (or expansion) amount of the display module and the thermal contraction (or expansion) amount of the frame, the display module and the frame may warp. When the display module and the frame warp, the screen integrity of the display panel may deteriorate, and the display apparatus may fail to provide a flat screen. In addition, one or more gaps between display modules may be irregularly formed.

In contrast, according to the present disclosure, the frame 100 may include the support bar 120. The support bar 120 may have a coefficient of thermal expansion lower than that of the panel 110. For example, the panel 110 may include aluminum, and the support bar 120 may include steel. The support bar 120 may suppress deformation of the display module 30 and the panel 110 due to one or more temperature changes. For example, the adhesive 90 may be disposed between the display module 30 and the frame 100 and cured at a high temperature to bond the display module 30 and the frame 100. When the display module 30 and the frame 100 are exposed from a high-temperature environment to a room-temperature environment after the curing of the adhesive 90, the support bar 120 may suppress contraction of the display module 30 and the panel 110. The support bar 120, having a coefficient of thermal expansion lower than those of the display module 30 and the panel 110, may prevent and/or reduce warping of the display module 30 and/or the panel 110 in accordance with one or more temperature changes after the curing of the adhesive 90. Accordingly, the screen integrity of the display panel 20 may not deteriorate, and the display apparatus 1 may provide a flat screen with improved stability and reliability. The gaps between the display modules 30A-30w may be maintained constant.

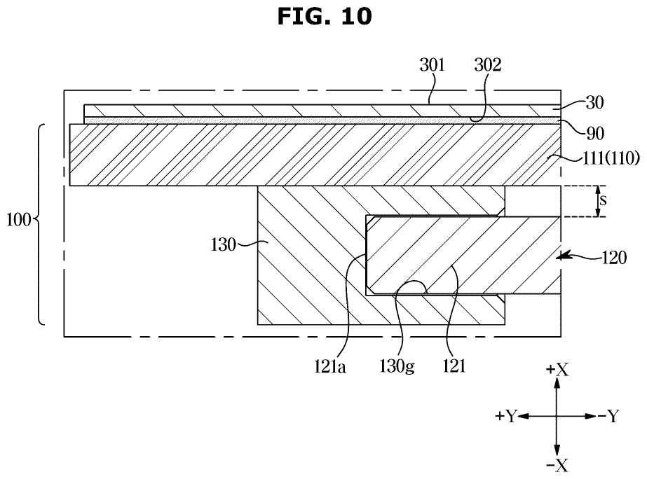

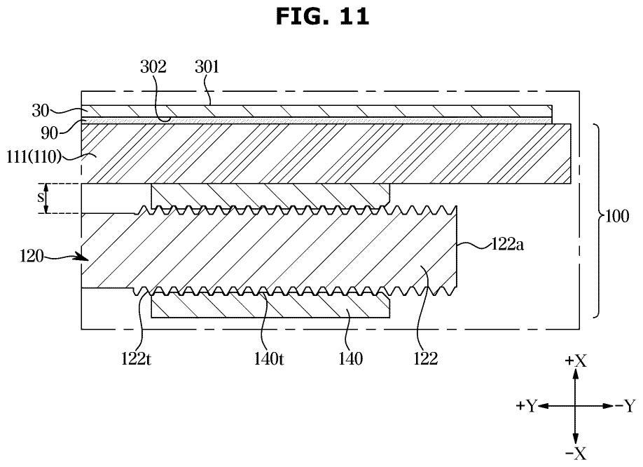

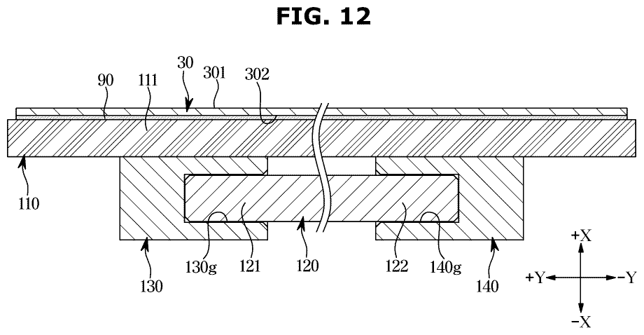

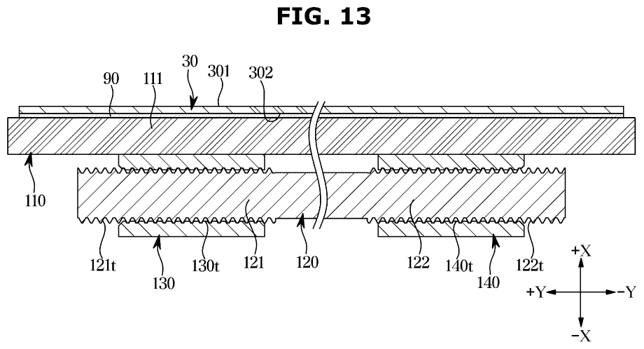

FIG. 10 is an enlarged view of portion A shown in FIG. 9. FIG. 11 is an enlarged view of portion B shown in FIG. 9. FIG. 12 is a plan cross-sectional view of an assembly of the display module and the frame according to an embodiment of the present disclosure. FIG. 13 is a plan cross-sectional view of an assembly of the display module and the frame according to an embodiment of the present disclosure.

Referring to FIG. 10 to 13, various examples of coupling methods for the support bar 120 will be described.

At least one of the first end portion 121 and the second end portion 122 of the support bar 120 may be inserted into a coupling portion formed on the rear side of the panel 110. At least one of the first end portion 121 and the second end 122 portion of the support bar 120 may be hook-coupled to a coupling portion formed on the rear side of the panel 110. At least one of the first end portion 121 and the second end portion 122 of the support bar 120 may be rotatably coupled to a coupling portion (e.g., via a screwing, threading, or any other suitable mechanism) formed on the rear side of the panel 110.

Referring to FIGS. 10 and 11, the first end portion 121 of the support bar 120 may be inserted into the first coupling portion 130, and the second end portion 122 of the support bar 120 may be rotatably coupled to the second coupling portion 140.

Referring to FIG. 10, the first coupling portion 130 may include a coupling groove 130g, and the first end portion 121 of the support bar 120 may be inserted into the coupling groove 130g. The coupling groove 130g of the first coupling portion 130 may be configured to receive the first end portion 121 of the support bar 120.

Referring to FIG. 11, the second coupling portion 140 may include a thread 140t, and the second end portion 122 of the support bar 120 may include a thread 122t. In response to rotation of the second end portion 122 relative to the second coupling portion 140, the thread 122t of the second end portion 122 and the thread 140t of the second coupling portion 140 may be engaged.

Referring to FIG. 12, the first end portion 121 of the support bar 120 may be inserted into the first coupling portion 130, and the second end portion 122 of the support bar 120 may be inserted into the second coupling portion 140. The first coupling portion 130 may include a first coupling groove 130g. The second coupling portion 140 may include a second coupling groove 140g. The first end portion 121 of the support bar 120 may be inserted into the first coupling groove 130g, and the second end portion 122 of the support bar 120 may be inserted into the second coupling groove 140g.

Referring to FIG. 13, the first end portion 121 of the support bar 120 may be rotatably coupled to the first coupling portion 130, and the second end portion 122 of the support bar 120 may be rotatably coupled to the second coupling portion 140. The first end portion 121 of the support bar 120 may include a first thread 121t, and the second end portion 122 of the support bar 120 may include a second thread 122t. The first coupling portion 130 may include a third thread 130t configured to engage with the first thread 121t. The second coupling portion 140 may include a fourth thread 140t configured to engage with the second thread 122t.

However, the present disclosure is not limited to the examples illustrated in FIGS. 10 to 13. The first end portion 121 of the support bar 120 may be coupled to the first coupling portion 130 by various known coupling methods, and the second end portion 122 of the support bar 120 may be coupled to the second coupling portion 140 by various known coupling methods.

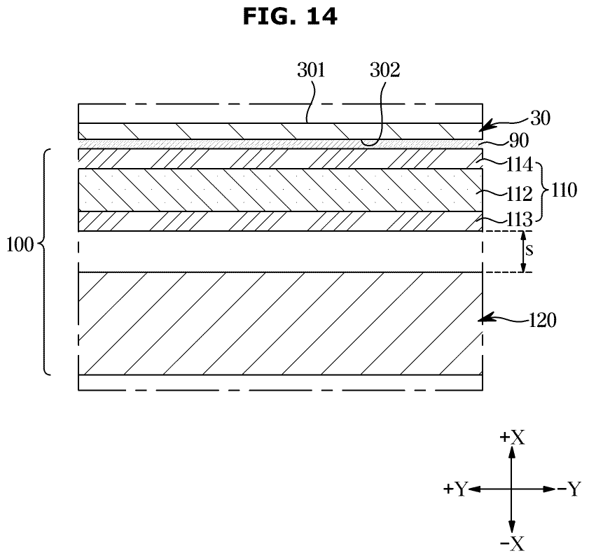

FIG. 14 is a plan cross-sectional view of an assembly of the display module and the frame according to an embodiment of the present disclosure.

The panel 110 of the frame 100 may be formed of a single layer or multiple layers.

For example, as shown in FIGS. 9 to 11, the panel 110 may include a single layer 111. The single layer 111 may form the front surface 110a and the rear surface 110b of the panel 110. The single layer 111 may include aluminum.

For example, referring to FIG. 14, the panel 110 may include a core layer 112, a first skin layer 114, and a second skin layer 113. The first skin layer 114 may be provided on a first surface of the core layer 112 and may be attached to the rear surface 302 of the display module 30. The first skin layer 114 may be attached to the rear surface 302 of the display module 30 by the adhesive 90. The first skin layer 114 may form the front surface 110a of the panel 110. The second skin layer 113 may be provided on a second surface of the core layer 112 opposite to the first surface. The second skin layer 113 may be disposed to face the support bar 120. The second skin layer 113 may form the rear surface 110b of the panel 110.

For example, the core layer 112 may include a plastic material. The core layer 112 may include polyethylene (PE) and may be referred to as a PE layer. For example, the first skin layer 114 and the second skin layer 113 may include aluminum. The first skin layer 114 may be referred to as a first aluminum layer, and the second skin layer 113 may be referred to as a second aluminum layer.

FIG. 15 is a plan cross-sectional view of a part of the display apparatus according to an embodiment of the present disclosure.

In FIG. 15, two display modules 30A and 30H are illustrated among the plurality of display modules 30A-30w. The two display modules 30A and 30H may be representative of the plurality of display modules 30A-30w. For convenience of description, the display module 30A may be referred to as a first display module 30A, and the display module 30H may be referred to as a second display module 30H.

In FIG. 15, two frames 100A and 100H are illustrated among the plurality of frames 100A-100w. The two frames 100A and 100H may be representative of the plurality of frames 100A-100w. For convenience of description, the frame 100A may be referred to as a first frame 100A, and the frame 100H may be referred to as a second frame 100H.

The first frame 100A may correspond to the first display module 30A. The first display module 30A may be supported by the first frame 100A. The first display module 30A and the first frame 100A may be coupled to each other by the adhesive 90. The first display module 30A and the first frame 100A may be bonded.

The second frame 100H may correspond to the second display module 30H. The second display module 30H may be supported by the second frame 100H. The second display module 30H and the second frame 100H may be coupled to each other by the adhesive 90. The second display module 30H and the second frame 100H may be bonded to each other.

As described above, the size of the display module 30 may be smaller than the size of the frame 100. The edge 101A of the first frame 100A may protrude outwardly from the edge 31A of the first display module 30A. The edge 103H of the second frame 100H may protrude outwardly from the edge 33H of the second display module 30H. The edge 103H of the second frame 100H may be arranged to be in contact with the edge 101A of the first frame 100A. Thus, the edge 31A of the first display module 30A and the edge 33H of the second display module 30H may be configured to be spaced apart. In other words, the gap g may be formed between the first display module 30A and the second display module 30H.

Generally, when a plurality of display modules are arranged in an M×N matrix form, collisions between display modules may occur. When this happens, at least one edge of the display module may be damaged by the impact. Furthermore, when tiling or assembling together multiple display modules, a large amount of time may be required to minimize collisions between adjacent ones of the display modules.

In contrast, according to the present disclosure, when the plurality of display modules 30A-30w are arranged in an M×N matrix form, the display modules 30A-30w may not interfere with each other. Because the size of the frame 100 is greater than that of the display module 30, the edge of any display module 30 may be spaced apart from the edge of other adjacent display modules 30. The gap g may be formed between one display module 30 and another display module 30. In other words, the plurality of display modules 30A-30w may be configured to be spaced apart from each other. Thus, collisions between the display modules 30A-30w and resulting damage may be prevented. Furthermore, tiling the plurality of display modules 30A-30w to realize a screen may be more easily accomplished. The manufacturing efficiency of the display apparatus 1 may be improved.

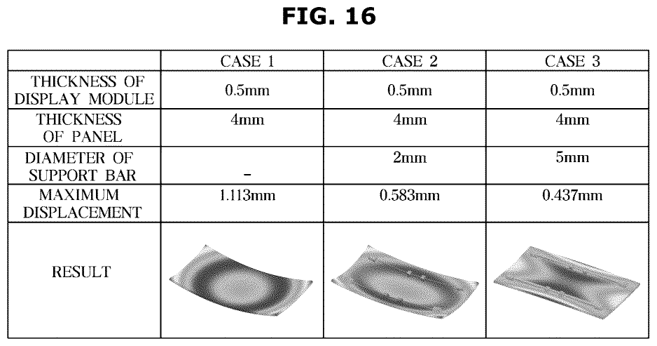

FIG. 16 is a table showing warpage (deformation) due to temperature changes in different cases. The table in FIG. 16 merely illustrates experimental examples, and the present disclosure may include various embodiments.

Referring to FIG. 16, case 1, case 2, and case 3 all include the display module 30 having a thickness of 0.5 mm and the panel 110 having a thickness of 4.0 mm. In cases 1, 2, and 3, the substrate 40 of the display module 30 includes borosilicate glass. Cases 1, 2, and 3 may be substantially the same, except for the support bar 120. Case 1 does not include the support bar 120. Case 2 includes two support bars 120 each having a diameter of 2 mm. Case 3 includes two support bars 120 each having a diameter of 5 mm. For cases 2 and 3, the two support bars 120 may be spaced apart along the vertical direction (Z direction).

Cases 1, 2, and 3 may be exposed to a room temperature environment of approximately 20° C. after curing of the adhesive 90 in a high temperature environment of approximately 80° C. In this case, the maximum amount of displacement (hereinafter referred to as ‘maximum displacement’) due to the temperature change of each case is as follows:

For case 1, the maximum displacement of the assembly of the display module 30 and the frame 100 is 1.113 mm.

For case 2, the maximum displacement of the assembly of the display module 30 and the frame 100 is 0.583 mm. For case 3, the maximum displacement of the assembly of the display module 30 and the frame 100 is 0.437 mm.

The maximum displacement in cases 2 and 3 is smaller than in case 1. When the frame 100 includes the support bar 120, deformation (warpage) of the assembly of the display module 30 and frame 100 may be more effectively reduced/suppressed compared to when the frame 100 does not include the support bar 120.

The maximum displacement in case 3 is smaller than in case 2. As the diameter of the support bar 120 increases, the support bar 120 may more effectively reduce/suppress deformation (warpage) of the assembly of the display module 30 and frame 100. However, the maximum displacement in a case where the diameter of each of the support bars 120 exceeds approximately 5 mm is not significantly different from the maximum displacement in case 3. In other words, when the diameter of the support bars 120 increases above a certain value, the effect of reducing deformation (warpage) of the assembly of the display module 30 and the frame 100 may not increase significantly.

It should be appreciated that the values indicated in FIG. 16 may vary depending on the shape, size, arrangement, number, and material, and the like of each component of the display apparatus 1 (the display module 30, the panel 110, the support bar 120).

According to various exemplary embodiments of the present disclosure, the display apparatus 1 may include: a display module 30 including a substrate 40 and a plurality of inorganic light-emitting devices 50 mounted on the substrate 40; a frame 100 configured to support the display module 30; and an adhesive 90 configured to be cured between the display module 30 and the frame 100 such that the display module 30 is coupled to the frame 10. The frame 100 may include a panel 110 attached to the rear surface 302 of the display module 30 and having a first coefficient of thermal expansion, and a support bar 120 disposed at the rear side of the panel 110 and having a second coefficient of thermal expansion lower than the first coefficient to prevent and/or reduce warping of the display module 30 and panel 110 due to temperature changes after curing of the adhesive 90.

The panel 110 may include aluminum. The support bar 120 may include steel.

The panel 110 may include a core layer 112, a first skin layer 114 disposed on the first surface of the core layer 112 and attached to the rear surface of the display module 30, and a second skin layer 113 disposed on the second surface of the core layer 112 opposite the first surface.

The core layer 112 may include plastic, resin, polymer, and/or any other suitable material. The first skin layer 114 and the second skin layer 113 may include aluminum.

A size of the display module 30 may be smaller than a size of the frame 100.

While the display module 30 and the frame 100 are coupled, an edge of the display module 30 may protrude outwardly from an edge of the frame 100.

The display apparatus 1 may further include a second display module 30H and a second frame 100H whose edge is arranged to contact the edge of the first frame 100A.

A gap g may be formed between the first display module 30A and the second display module 30H.

The frame 100 may include a first coupling portion 130 formed on the rear surface of the panel 110 and a second coupling portion 140 formed on the rear surface of the panel 110 and spaced apart from the first coupling portion 130.

The first end portion 121 of the support bar 120 may be configured to be coupled to the first coupling portion 130, and the second end portion 122 of the support bar 120 may be configured to be couplable to the second coupling portion 140.

The first end portion 121 of the support bar 120 may be coupled to the first coupling portion 130 by insertion, and the second end portion 122 of the support bar 120 may be coupled to the second coupling portion 140 by rotation.

The first coupling portion 130 may include a first coupling groove 130g, the second coupling portion 140 may include a second coupling groove 140g, the first end portion 121 of the support bar 120 may be inserted into the first coupling groove 130g, and the second end portion 122 may be inserted into the second coupling groove 140g.

The first end portion 121 of the support bar 120 may include a first thread 121t, and the second end portion 122 of the support bar 120 may include a second thread 122t, the first coupling portion 130 may include a third thread 130t configured to engage with the first thread 121t, and the second coupling portion 140 may include a fourth thread 140t configured to engage with the second thread 122t.

The substrate 40 may include glass.

The adhesive 90 may include epoxy resin.

According to various exemplary embodiments of the present disclosure, a display apparatus 1 may include: a display module 30 including a substrate 40 and a plurality of inorganic light-emitting elements 50 mounted on the substrate 40; and a frame 100 configured to support the display module 30. The frame 100 may include a panel 110 attached to a rear surface 302 of the display module 30. The panel 110 may include aluminum. The frame 100 may include a support bar 120 disposed at a rear side of the panel 110 so as to suppress deformation of the display module 30 and the panel 110 caused by temperature changes. The support bar 120 may include steel.

The display apparatus 1 may further include an adhesive 90 provided between the display module 30 and the frame 100 so as to be cured and bond the display module 30 and the frame 100 to each other.

The adhesive 90 may be cured in a temperature range of 75° C. to 100° C.

The size of the display module 30 may be smaller than the size of the frame 100.

The display modules 30 may be provided in plural and may be spaced apart from one another.

According to various exemplary embodiments of the present disclosure, the support bar 120 may reduce and/or prevent deformation (warpage) of the display module 30 and/or frame 100 assembly caused by one or more temperature changes, thereby enabling the display apparatus 1 to implement and maintain a flat screen. Furthermore, because a gap g is formed between adjacent display modules 30, the edges of the display modules can be protected from damage due to collisions therebetween.

The effects, improvements, and/or advantages achieved by the present disclosure are not limited to those mentioned above, and other effects not mentioned will be clearly understood by those skilled in the art to which the present disclosure belongs based on the description above.

While the present disclosure has been particularly described with reference to exemplary embodiments, it should be understood by those of skilled in the art that various changes in form and details may be made without departing from the spirit and scope of the present disclosure.

What is claimed is:

1. A display apparatus comprising:
a display module comprising a substrate and a plurality of inorganic light-emitting elements on the substrate;
a frame configured to support the display module; and
an adhesive configured to be cured between the display module and the frame,
wherein the frame comprises:
a panel on a rear surface of the display module with the adhesive therebetween, the panel having a first coefficient of thermal expansion (CTE); and
a support bar disposed on a rear side of the panel and having a second CTE lower than the first CTE.

2. The display apparatus according to claim 1, wherein
the panel comprises aluminum, and
the support bar comprises steel.

3. The display apparatus according to claim 1, wherein the panel comprises:
a core layer;
a first skin layer on a first surface of the core layer and on the rear surface of the display module; and
a second skin layer on a second surface of the core layer opposite the first surface.

4. The display apparatus according to claim 3, wherein
the core layer comprises plastic, and
the first skin layer and/or the second skin layer comprise aluminum.

5. The display apparatus according to claim 1, wherein a size of the display module is smaller than a size of the frame.

6. The display apparatus according to claim 5, wherein an edge of the display module protrudes outwardly from an edge of the frame.

7. The display apparatus according to claim 6, wherein
the display module is a first display module,
the frame is a first frame corresponding to the first display module, and
the display apparatus further comprises:
a second display module; and
a second frame corresponding to the second display module, wherein an edge of the second frame contacts an edge of the first frame.

8. The display apparatus according to claim 7, further comprising a gap between the first display module and the second display module.

9. The display apparatus according to claim 1, wherein the frame comprises:
a first coupling portion on a rear surface of the panel; and
a second coupling portion on the rear surface of the panel and apart from the first coupling portion.

10. The display apparatus according to claim 9, wherein a first end portion of the support bar is configured to be couplable to the first coupling portion, and a second end portion of the support bar is configured to be couplable to the second coupling portion.

11. The display apparatus according to claim 10, wherein the first end portion of the support bar is coupled to the first coupling portion by insertion, and the second end portion of the support bar is coupled to the second coupling portion by rotation.

12. The display apparatus according to claim 10, wherein
the first coupling portion comprises a first coupling groove,
the second coupling portion comprises a second coupling groove,
the first end portion of the support bar is in the first coupling groove, and
the second end portion of the support bar is in the second coupling groove.

13. The display apparatus according to claim 10, wherein
the first end portion of the support bar comprises a first thread,
the second end portion of the support bar comprises a second thread,
the first coupling portion comprises a third thread configured to engage with the first thread, and
the second coupling portion comprises a fourth thread configured to engage with the second thread.

14. The display apparatus according to claim 1, wherein the substrate comprises glass.

15. The display apparatus according to claim 1, wherein the adhesive comprises epoxy resin.

16. The display apparatus according to claim 1, wherein the support bar is configured to prevent and/or reduce warping of the display module and/or the panel due to a temperature change after curing the adhesive.
